(19) United States
(12) Patent Application Publication
(10) Pub. No.: US 2018/0166502 A1
(43) Pub. Date: Jun. 14, 2018

(54) SEMICONDUCTOR DEVICE INCLUDING A LINE PATTERN HAVING THRESHOLD SWITCHING DEVICES

(71) Applicant: Samsung Electronics Co., Ltd., Suwon-si (KR)

(72) Inventor: Masayuki TERAI, Suwon-si (KR)

(73) Assignee: Samsung Electronics Co., Ltd., Suwon-si (KR)

(21) Appl. No.: 15/630,169

(22) Filed: Jun. 22, 2017

(30) Foreign Application Priority Data
Dec. 8, 2016 (KR) 10-2016-0166835

(51) Int. Cl. H01L 27/24; H01L 45/00

(52) U.S. Cl. CPC H01L 27/2481; H01L 45/06; H01L 45/1253

(57) ABSTRACT

Some example embodiments relate to a semiconductor device including a line pattern, the line pattern having threshold switching devices. The semiconductor device includes a line pattern disposed on a semiconductor substrate. The line pattern includes threshold switching devices and switch separation regions. Data storage patterns may overlap the threshold switching devices. Intermediate electrodes may be disposed between the data storage patterns and the threshold switching devices. The line pattern includes an impurity element, and the concentration of the impurity element in the switch separation regions is higher than the concentration of the impurity element in the threshold switching devices.

### CROSS-REFERENCE TO RELATED APPLICATION

This application claims the benefit of priority from Korean Patent Application No. 10-2016-0166835, filed on Dec. 8, 2016 in the Korean Intellectual Property Office, the disclosure of which is incorporated herein by reference in its entirety.

### BACKGROUND

### 1. Field

The inventive concepts relate to a semiconductor device including a line pattern having threshold switching devices.

### 2. Description of Related Art

In general, memory cells of semiconductor devices, such as a phase-change random access memory (PRAM) or the like, have used a p-n diode or a metal oxide semiconductor (MOS) transistor as a switching device. Recently, to improve a degree of integration of semiconductor devices, instead of a switching device such as a p-n diode or a MOS transistor, a threshold switching device in which a resistance value is rapidly changed at a specific voltage level has been proposed to be included in one or more memory cells of one or more semiconductor devices.

### SUMMARY

Some example embodiments of the inventive concepts relate to a semiconductor device including a line pattern having one or more threshold switching devices.

Some example embodiments of the inventive concepts relate to a semiconductor device which may improve a degree of integration.

Some example embodiments of the inventive concepts relate to a semiconductor device. The semiconductor device may include a line pattern disposed on a semiconductor substrate. The line pattern may include threshold switching devices and switch separation regions. Data storage patterns may overlap the threshold switching devices. Intermediate electrodes may be disposed between the data storage patterns and the threshold switching devices. The line pattern may include an impurity element, and the concentration of the impurity element in the switch separation regions may be higher than the concentration of the impurity element in the threshold switching devices.

According to some example embodiments of the inventive concepts, a semiconductor device may be provided. The semiconductor device may include first conductive lines disposed on a semiconductor substrate. The first conductive lines may extend in a first direction. A lower structure may be disposed on the first conductive lines. The lower structure may include line patterns disposed on the first conductive lines and extending in the first direction, second conductive lines disposed on a level higher than a level of the line patterns and extending in a second direction substantially perpendicular to the first direction, and data storage patterns disposed between the first conductive lines and the second conductive lines. Each, or at least one, of the line patterns may include threshold switching devices overlapping the second conductive lines, and switch separation regions disposed between the threshold switching devices and having different physical properties from the threshold switching devices.

Some example embodiments relate to a semiconductor device including a line pattern on a semiconductor substrate and including a plurality of threshold switching devices alternating with a plurality of switch separation regions in a length direction of the line pattern, and data storage patterns overlapping the threshold switching devices. In the semiconductor device, a threshold voltage of the switch separation regions is higher than a threshold voltage of the threshold switching devices, or an off-current of the switch separation regions is lower than an off-current of the threshold switching devices.

### BRIEF DESCRIPTION OF DRAWINGS

The above, and other example embodiments, features, and advantages thereof will be more clearly understood from the following detailed description when taken in conjunction with the accompanying drawings, in which:

FIGS. 1A and 1B are perspective views of a semiconductor device according to an example embodiment of the inventive concepts;

FIG. 2 is a perspective view of a modified example of a semiconductor device according to an example embodiment of the inventive concepts;

FIGS. 3A and 3B are perspective views of another modified example of a semiconductor device according to an example embodiment of the inventive concepts;

FIG. 4 is a perspective view of another modified example of a semiconductor device according to an example embodiment of the inventive concepts;

FIG. 5 is a perspective view of another modified example of a semiconductor device according to an example embodiment of the inventive concepts;

FIG. 6 is a perspective view of another modified example of a semiconductor device according to an example embodiment of the inventive concepts;

FIG. 7 is a perspective view of another modified example of a semiconductor device according to an example embodiment of the inventive concepts; and

FIGS. 8A through 8M are perspective views of an example of a method of fabricating a semiconductor device according to an example embodiment of the inventive concepts.

### DETAILED DESCRIPTION

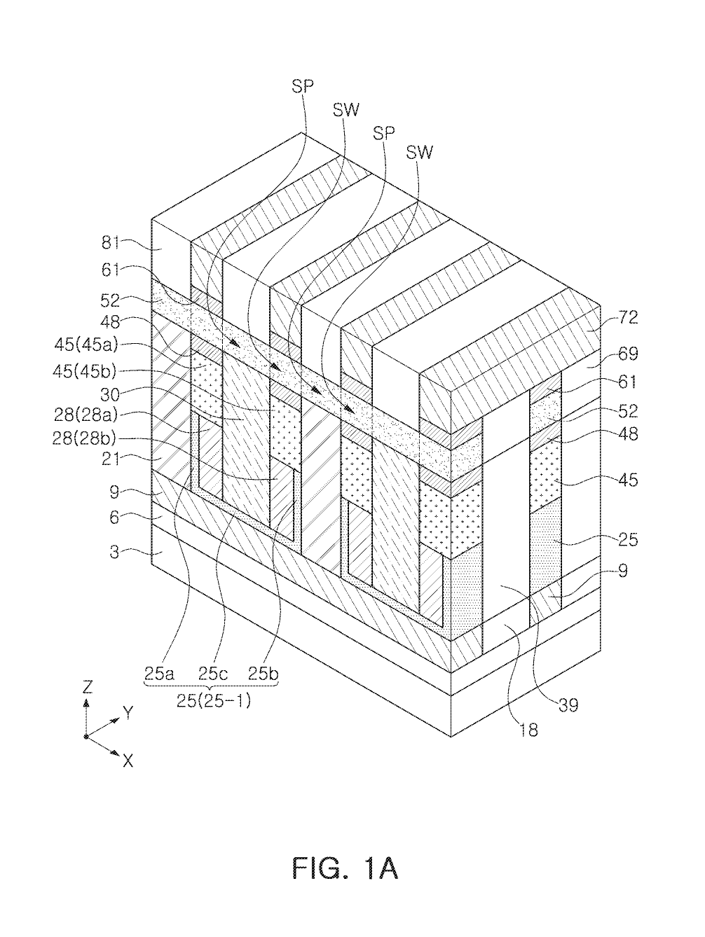

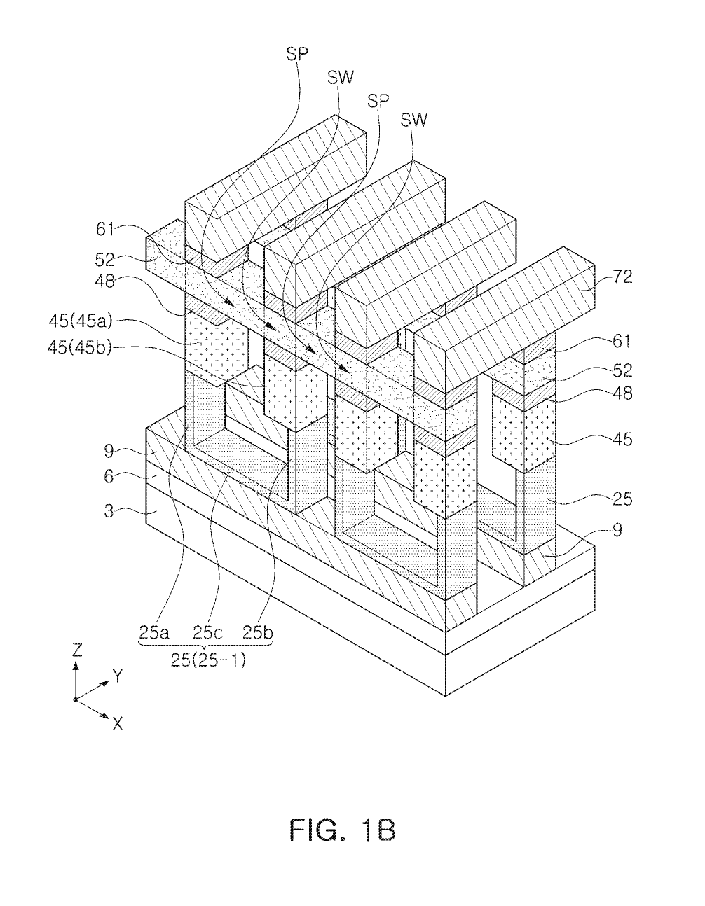

With reference to FIGS. 1A and 1B, an example of a semiconductor device according to an example embodiment of the inventive concepts will be described. FIGS. 1A and 1B are perspective views of a semiconductor device according to an example embodiment. FIG. 1B is a perspective view of some components illustrated in FIG. 1A in order to help understand FIG. 1A.

Referring to FIGS. 1A and 1B, a semiconductor substrate 3 may have a lower insulating layer 6 disposed thereon. The semiconductor substrate 3 may be formed of or include a semiconductor material such as silicon. The lower insulating layer 6 may be formed of or include an insulating material such as silicon oxide or the like.

The lower insulating layer 6 may have first conductive lines 9 disposed thereon. The first conductive lines 9 may be formed of or include a conductive material such as doped silicon, a metal (e.g., tungsten (W) or the like), metallic nitride (e.g., titanium nitride (TiN) or tungsten nitride (WN) or the like), and/or a metal silicide (e.g., tungsten silicide (WSi) or titanium silicide (TiSi) or the like) or the like. The first conductive lines 9 may fill a space between the first conductive lines 9. The first gap-fill layers 18 may be formed of or include an insulating material such as silicon oxide.

The first conductive lines 9 may have first insulating patterns 21 disposed thereon to be spaced apart from each other. The first insulating patterns 21 may be formed of or include an insulating material such as silicon oxide or silicon nitride.

The first insulating patterns 21 may have first electrodes 25 disposed therebetween. The first electrodes 25 may be disposed on the first conductive lines 9 to be electrically connected to the first conductive lines 9. The first electrodes 25 may be formed of or include a conductive material including at least one of titanium nitride (TiN), titanium aluminum nitride (TiAlN), tantalum nitride (TaN), WN, molybdenum nitride (MoN), titanium silicon nitride (TiSiN), titanium carbon nitride (TiCN), titanium boron nitride (TiBN), zirconium silicon nitride (ZrSiN), tungsten silicon nitride (WSiN), tungsten boron nitride (WBN), zirconium aluminum nitride (ZrAlN), molybdenum aluminum nitride (MoAlN), tantalum silicon nitride (TaSiN), tantalum aluminum nitride (TaAlN), TiSi, titanium tungsten (TiW), titanium aluminum (TiAl), titanium oxygen nitride (TiON), titanium aluminum oxygen nitride (TiAlON), tungsten oxygen nitride (WON), tantalum oxygen nitride (TaON), W, platinum (Pt), iridium (Ir), ruthenium (Ru), or combinations thereof. Each of the first electrodes 25 may include a first portion 25a and a second portion 25b, substantially parallel to and opposing each other, and a connection portion 25c connecting lower regions of the first and second portions 25a and 25b. The connection portions 25c of the first electrodes 25 may contact the first conductive lines 9.

Spacer patterns 28 and second insulating patterns 30 may be disposed on the connection portions 25c of the first electrodes 25. The spacer patterns 28 may be formed of or include an insulating material. The second insulating patterns 30 may be disposed between the spacer patterns 28. A first electrode 25-1 of the first electrodes 25 is illustrated as an example. Each of the spacer patterns 28 may include a first spacer pattern 28a disposed on the connection portion 25 of the first electrode 25-1 to contact the first portion 25a of the first electrode 25-1, and a second spacer pattern 28b disposed on the connection portion 25 of the first electrode 25-1 to contact the second portion 25b of the first electrode 25-1. The first and second spacer patterns 28a and 28b may be spaced apart from each other, and may have a single second insulating pattern 30 disposed therebetween. Upper surfaces of the first electrodes 25 and the spacer patterns 28 may be lower than upper surfaces of the first and second insulating patterns 21 and 30.

The first electrodes 25 and the spacer patterns 28 may have data storage patterns 45 disposed thereon.

In an example embodiment, the data storage patterns 45 may be formed of or include a phase change memory material whose phase switches between an amorphous phase having high resistivity and a crystalline phase having low resistivity, according to temperatures and times at which the phase change memory material is heated by an applied current. For example, the phase change memory material that may be used as the data storage patterns 45 may be a chalcogenide material including germanium (Ge), antimony (Sb), and/or tellurium (Te). Alternatively, the phase change memory material may also be a material including at least one of Te or selenium (Se) and at least one of Ge, Sb, bismuth (Bi), lead (Pb), tin (Sn), arsenic (As), sulfur (S), Si, phosphorus (P), oxygen (O), nitrogen (N), or indium (In).

Lower surfaces of the data storage patterns 45 may contact the upper surfaces of the first electrodes 25 and the upper surfaces of the spacer patterns 28. The data storage patterns 45 may include a first data storage pattern 45a and a second data storage pattern 45b spaced apart from each other. The lower surface of the first data storage pattern 45a may contact the upper surface of the first portion 25a of the first electrode 25-1 of the first electrodes 25 and the upper surface of the first spacer pattern 28a, and the lower surface of the second data storage pattern 45b may contact the upper surface of the second portion 25b of the first electrode 25-1 and the upper surface of the second spacer pattern 28b.

In an example embodiment, the first conductive lines 9 may be word lines of a phase change memory device, the first electrodes 25 may be a lower electrode or a heater of the phase change memory device, and the data storage patterns 45 may be formed of or include the phase change memory material that may store information of the phase change memory device. The first and second portions 25a and 25b of the first electrodes 25 may reduce a contact area between the data storage patterns 45 and the first electrodes 25 to thus reduce a level of reset current of the semiconductor device, such as the phase change memory device. In addition, the connection portions 25c of the first electrodes 25 may increase a contact area between the first conductive lines 9 and the first electrodes 25, to thus reduce a level of contact resistance between the first conductive lines 9 and the first electrodes 25. Thus, electrical characteristics of the semiconductor device may be improved.

The data storage patterns 45 may have intermediate electrodes 48 disposed thereon. The intermediate electrodes may contact the data storage patterns 45. The intermediate electrodes may be formed of or include a conductive material such as a metal and/or metal nitride.

The first gap-fill layers 18 may have third insulating patterns 39 disposed thereon. The first to third insulating patterns 21, 30, and 39 may be formed of or include an insulating material such as silicon oxide or silicon nitride. The spacer patterns 28 may be formed of or include a material having a different etching selectivity from the first to third insulating patterns 21, 30, and 39. For example, when the first to third insulating patterns 21, 30, and 39 are formed of or include silicon nitride, the spacer patterns 28 may be formed of or include silicon oxide. Conversely, when the first to third insulating patterns 21, 30, and 39 are formed of or include silicon oxide, the spacer patterns 28 may be formed of or include silicon nitride.

The upper surfaces of the first and second insulating patterns 21 and 30 and upper surfaces of the third insulating patterns 39 may be coplanar with one another. The upper surfaces of the first to third insulating patterns 21, 30, and 39 may also be coplanar with those of the intermediate electrodes 48.

The intermediate electrodes 48 and the first and second insulating patterns 21 and 30 may have line patterns 52 disposed thereon. The line patterns 52 may overlap the first conductive lines 9. Each of the line patterns 52 may include threshold switching devices SW and switch separation regions SP. The switch separation regions SP may be disposed between the threshold switching devices SW. The threshold switching devices may be an ovonic threshold switching device. When a voltage having a magnitude equal to or greater than the magnitude of a threshold voltage (Vth) is applied to the threshold switching devices SW, the threshold switching devices SW may switch from an OFF state to an ON state. Thus, use of such a threshold voltage (Vth) may enable the threshold switching devices SW to switch between the OFF state and the ON state, so that the threshold switching devices SW may be used as a switch of the semiconductor device. For example, the threshold switching devices SW may be used as memory cell switches of a memory cell array of the semiconductor device, such as the phase change memory device.

The line patterns 52 may include a threshold switch material and a switch separation material. The switch separation material may be formed of or include the threshold switch material, injected or doped with an element which changes the physical properties of the threshold switch material. The threshold switching devices SW may be formed of or include the threshold switch material, and the switch separation regions SP may be formed of or include the switch separation material.

The threshold switch material of the threshold switching devices SW may be a chalcogenide-based material different from a chalcogenide material that may be used in the data storage patterns 45. For example, the data storage patterns 45 may be formed of or include a phase change memory material (e.g., an alloy of Ge, Sb, and/or Te, or the like) whose phase may switch between a crystalline phase and an amorphous phase and vice versa during operations of the semiconductor device, and the threshold switching devices SW may be formed of or include a chalcogenide-based ovonic threshold switch material that may maintain the amorphous phase thereof during operations of the semiconductor device. Even when a voltage having a magnitude equal to or greater than the magnitude of the threshold voltage (Vth) is applied to the threshold switching devices SW and the threshold switching devices SW switch from the OFF state to the ON state, the threshold switching devices SW may not be crystallized in the amorphous phase.

The threshold switching devices SW may include an alloy material including at least two of As, S, Se, Te, or Ge, or an element (e.g., Si or N) added to the alloy material so as to maintain the amorphous phase at a higher temperature. Alternatively, the threshold switching devices SW may be formed of or include at least one of an alloy material including Te, As, Ge, and Si, an alloy material including Ge, Te, and Pb, an alloy material including Ge, Se, and Te, an alloy material including Al, As, and Te, an alloy material including Se, As, Ge, and Si, an alloy material including Se, As, Ge, and C, an alloy material including Se, Te, Ge, and Si, an alloy material including Ge, Sb, Te, and Se, an alloy material including Ge, Bi, Te [symbol] Se, an alloy material including Ge, As, Sb, and Se, an alloy material including Ge, As, Bi, and Te, or an alloy material including Ge, As, Bi, and Se.

The switch separation regions SP may further include an element that may change physical properties of the threshold switch material rather than the threshold switching devices SW. In an example embodiment, the physical properties of the threshold switch material may be threshold voltage characteristics or off-current (Ioff) characteristics. For example, a threshold voltage of the switch separation regions SP may be higher than a threshold voltage of the threshold switching devices SW. Alternatively, an off-current (Ioff) of the switch separation regions SP may be lower than an off-current (Ioff) of the threshold switching devices SW.

Throughout the specification, an “element that may change the physical properties of the threshold switch material” may be defined as an “impurity element.” Such a term “impurity element” may be used to facilitate understanding of the various example embodiments, and the various example embodiments of the inventive concepts are not limited thereto. For example, throughout the detailed description and the claims, the term “impurity element” may be replaced by a term “physical property change element” or “additional element.”

In this case, the line patterns 52 may include an impurity element, and the concentration of the impurity element in the switch separation regions SP may be higher than the concentration of the impurity element in the threshold switching devices SW.

In an example embodiment, the impurity element may be any one of N, As, Si, or Ge. The impurity element may also be oxygen (O).

The switch separation regions SP may be interposed between the threshold switching devices SW to reduce or prevent an undesired level of current from flowing between the threshold switching devices SW, disposed in a single line pattern 52. The switch separation regions SP may reduce or prevent a leakage current between the threshold switching devices SW. In addition, the switch separation regions SP may electrically separate the threshold switching devices SW to reduce or prevent interference between the threshold switching devices SW, even when an interval between the threshold switching devices SW is reduced. Thus, the threshold switching devices SW may be denser. Thus, a degree of integration of the semiconductor device may be improved.

The line patterns 52 may have second gap-fill layers 69 disposed therebetween. The second gap-fill layers 69 may be formed of or include an insulating material such as silicon oxide or the like. The second gap-fill layers 69 may overlap the third insulating patterns 39.

The line patterns 52 may have second conductive lines 72 disposed thereon. The second conductive lines 72 may be disposed on a level higher than the level of the line patterns 52. The first conductive lines 9 and the line patterns 52 may have line shapes extending in a first direction X, and the second conductive lines 72 may have a line shape extending in a second direction Y, substantially perpendicular to the first direction X. The first and second directions X and Y may be defined to be on the same plane. For example, the first and second directions X and Y may be defined to be on a surface substantially parallel to the semiconductor substrate 3.

The second conductive lines 72 may be formed of or include a conductive material such as a metal and/or metal nitride. The second conductive lines 72 may fill a space between the second conductive lines 72. The third gap-fill layers 81 may be formed of or include an insulating material such as silicon oxide or the like.

The second conductive lines 72 and the line patterns 52 may have second electrodes 61 disposed therebetween. The second electrodes 61 may be disposed between the threshold switching devices SW of the line patterns 52 and the second conductive lines 72. The second electrodes 61 may overlap the threshold switching devices SW. The second electrodes 61 may be formed of or include a conductive material such as a metal and/or metal nitride.

The first electrodes 25 may also be referred to as a lower electrode, and the second electrodes 61 may also be referred to as an upper electrode. The second electrodes 61 and the intermediate electrodes 48 may be opposite each other, with the threshold switching devices SW of the line patterns 52 interposed therebetween.

In an example embodiment, the first conductive lines 9 may be a word line, and the second conductive lines 72 may be a bit line. Memory cells may be disposed in regions in which the first and second conductive lines 9 and 72 intersect. Such memory cells may include the threshold switching devices SW and the data storage patterns 45.

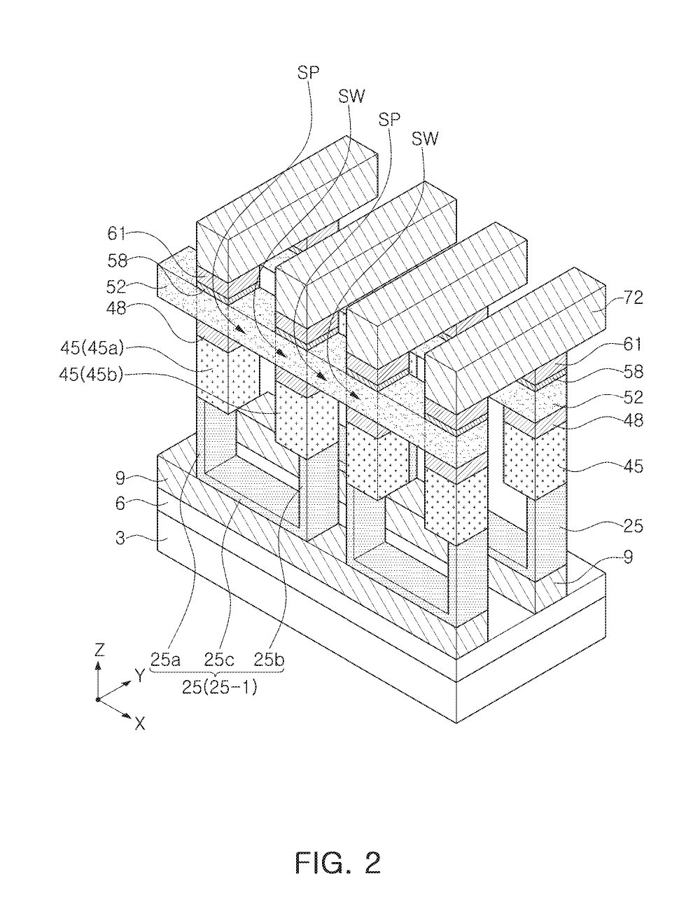

In an example embodiment, the second electrodes 61 may directly contact the threshold switching devices SW. However, the inventive concepts are not limited thereto. For example, the second electrodes 61 and the threshold switching devices SW may have buffer patterns interposed therebetween. Such buffer patterns will be described with reference to FIG. 2, which is a perspective view of a modified example of a semiconductor device according to an example embodiment of the inventive concepts.

Referring to FIG. 2, the second electrodes 61 and the threshold switching devices SW described in relation to FIGS. 1A and 1B may have buffer patterns 58 interposed therebetween. The buffer patterns 58 may directly contact the threshold switching devices SW. The second electrodes 61 may be electrically connected to the threshold switching devices SW through the buffer patterns 58. The buffer patterns 58 may be formed of or include a conductive material. The buffer patterns 58 may also be formed of or include a thin carbon layer.

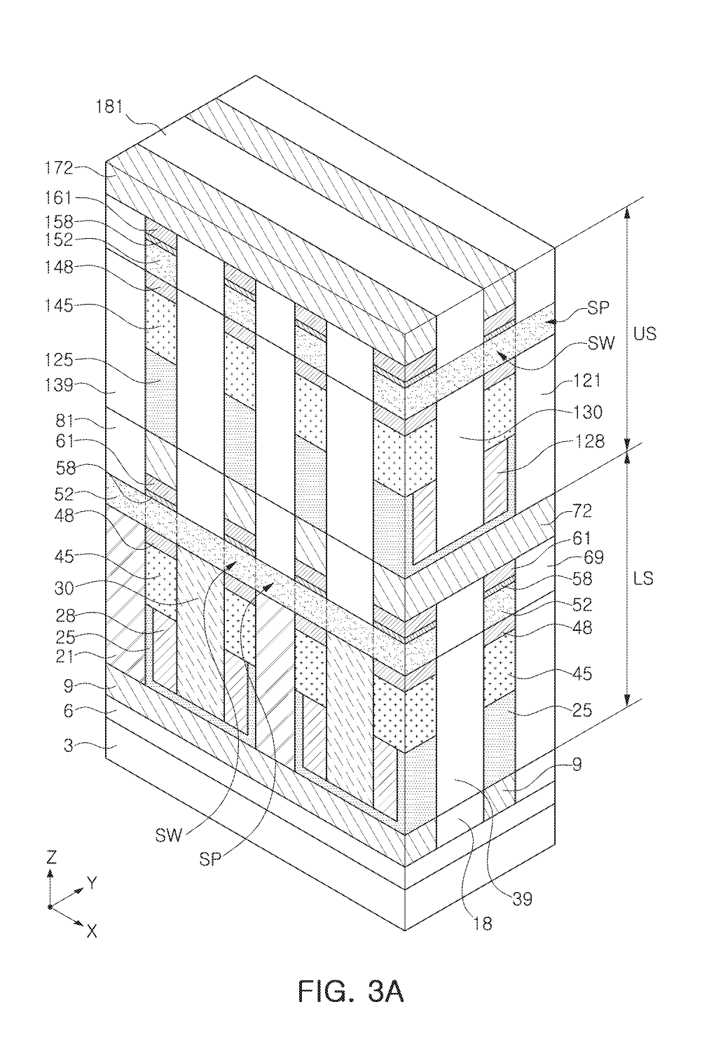

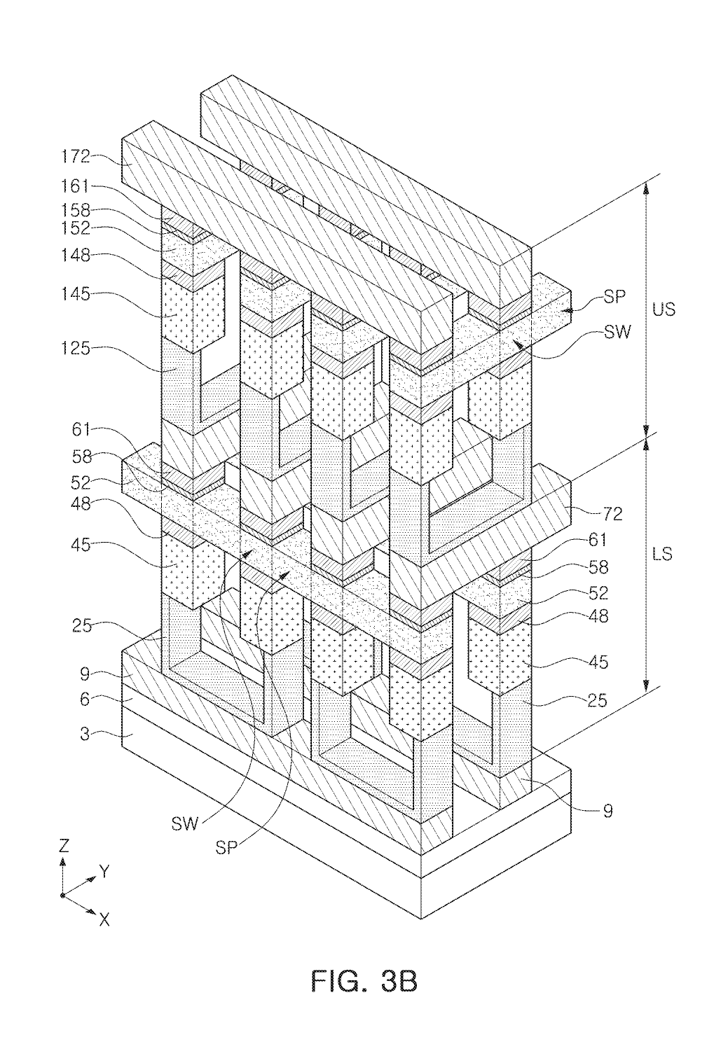

With reference to FIGS. 3A and 3B, another modified example of a semiconductor device according to an example embodiment of the inventive concepts will be described. FIGS. 3A and 3B are perspective views of another modified example of a semiconductor device according to an example embodiment of the inventive concepts. FIG. 3B is the perspective view of some components illustrated in FIG. 3A, in order to help understand FIG. 3A.

Referring to FIGS. 3A and 3B, the semiconductor substrate 3, as illustrated in FIGS. 1A and 1B, may have the first conductive lines 9 and the first gap-fill layers 18 disposed on the lower insulating layer 6 thereof.

The first conductive lines 9 and the first gap-fill layers 18 may have a lower structure LS disposed thereon. The lower structure LS may include the first to third insulating patterns 21, 30, and 39, the first electrodes 25, the spacer patterns 28, the data storage patterns 45, the intermediate electrodes 48, the line patterns 52, the second gap-fill layers 69, the buffer patterns 58, the second electrodes 61, the second conductive lines 72, and the third gap-fill layers 81, illustrated in FIGS. 1A and 1B.

The lower structure LS may have an upper structure US disposed thereon, and the upper structure US may be formed by rotating a structure, the same as the lower structure LS, in the second direction Y substantially perpendicular to the first direction X, by 90° from the first direction X. For example, the first and second directions X and Y may be defined to be on the same plane as the surface of the semiconductor substrate 3. Thus, the upper structure US may include third electrodes 125, corresponding to the first electrodes 25 of the lower structure LS, upper data storage patterns 145, corresponding to the data storage patterns 45 of the lower structure LS, intermediate electrodes 148, corresponding to the intermediate electrodes 48 of the lower structure LS, upper line patterns 152, corresponding to the line patterns 52 of the lower structure LS, upper buffer patterns 158, corresponding to the buffer patterns 58 of the lower structure LS, fourth electrodes 161, corresponding to the second electrodes 61 of the lower structure LS, and third conductive lines 172, corresponding to the second conductive lines 72 of the lower structure LS. The upper structure US may be electrically connected to the second conductive lines 72 of the lower structure LS. For example, the third electrodes 125 of the upper structure US may be electrically connected to the second conductive lines 72 of the lower structure LS. In addition, the upper structure US may have fourth to sixth insulating patterns 121, 130, and 139, spacer patterns 128, and fourth and fifth gap-fill layers 169 and 181 disposed therein to correspond to the first to third insulating patterns 21, 30, and 39, the spacer patterns 28, and the second and third gap-fill layers 69 and 81 of the lower structure LS, respectively.

The upper line patterns 152 of the upper structure US may include threshold switching devices SW and switch separation regions SP, as illustrated in the line patterns 52 of the lower structure LS.

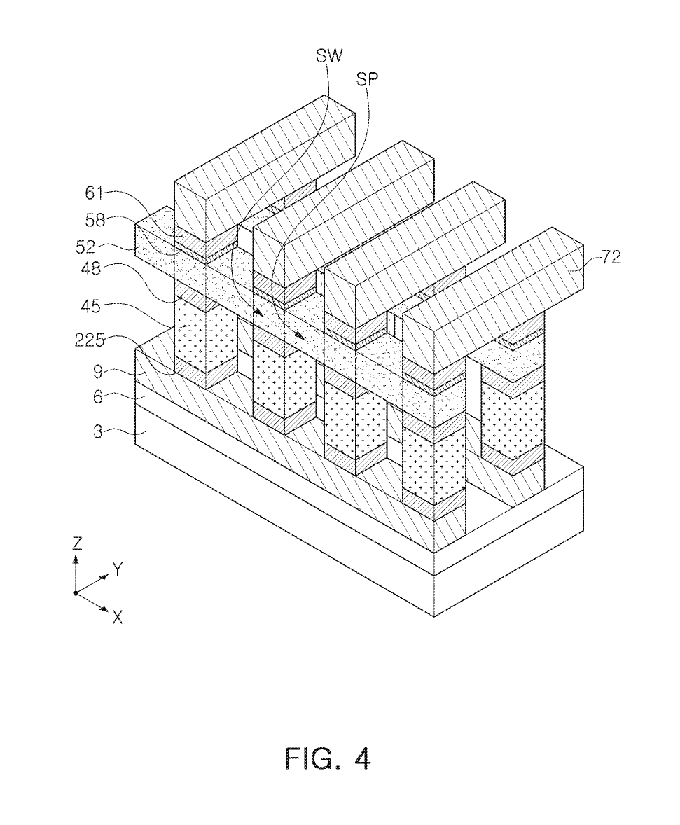

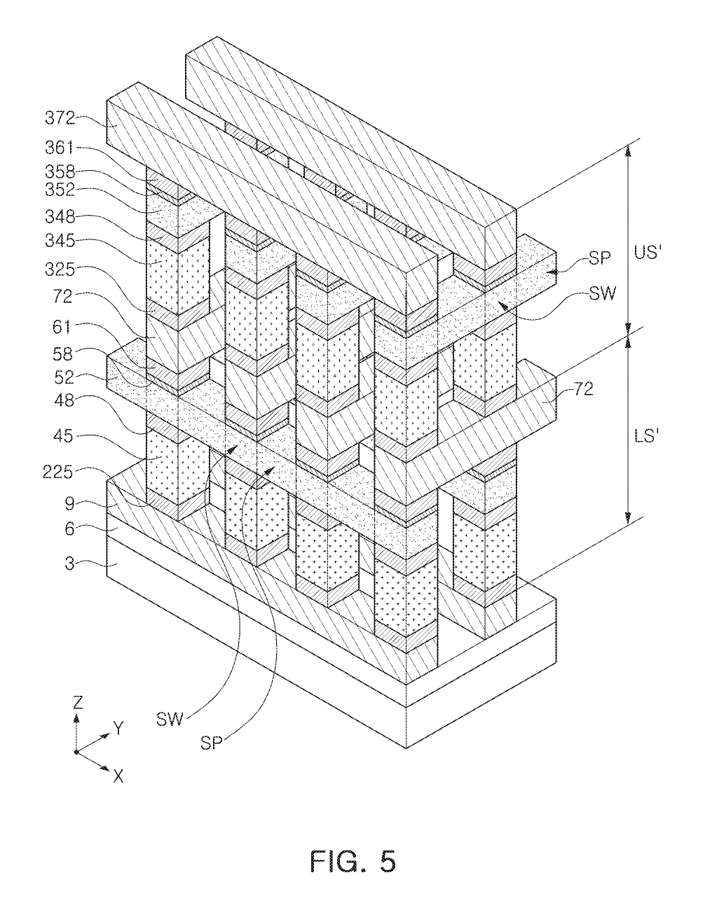

In some example embodiments, the first electrodes 25 may include the first and second portions 25a and 25b, to reduce a contact area between the first electrodes 25 and the data storage patterns 25, thus significantly reducing a level of reset current of the phase change memory device. However, the inventive concepts are not limited thereto. For example, in order to reduce production costs, the first electrodes 25 may be replaced by electrodes that may be formed more easily than the first electrodes 25. Examples of a semiconductor device including electrodes that may replace the first electrodes 25 as described above will be described with reference to FIGS. 4 and 5.

With reference to FIG. 4, another modified example of a semiconductor device according to an example embodiment of the inventive concepts will be described. FIG. 4 is a perspective view of another modified example of a semiconductor device according to an example embodiment.

Referring to FIG. 4, the semiconductor substrate 3 may have the first conductive lines 9 disposed on the lower insulating layer 6 thereof, as illustrated in FIGS. 1A and 1B. The semiconductor substrate 3 may have the line patterns 52, including the threshold switching devices SW and the switch separation regions SP illustrated in FIGS. 1A and 1B. The line patterns 52 may overlap the first conductive lines 9.

The first conductive lines 9 and the line patterns 52 may have first electrodes 225 disposed therebetween. The data storage patterns 45 and the intermediate electrodes 48 illustrated in FIGS. 1A and 1B may be disposed between the first electrodes 225 and the line patterns 52. The first electrodes 225, the data storage patterns 45, and the intermediate electrodes 48 may be stacked, for example sequentially stacked on the first conductive lines 9, and may have lateral surfaces aligned in a vertical direction thereof. The second electrodes 61 and the second conductive lines 72 illustrated in FIGS. 1A and 1B may be disposed on the line patterns 52.

In an example embodiment, the second electrodes 61 and the line patterns 52 may have the buffer patterns 58 therebetween, as illustrated in FIG. 2.

With reference to FIG. 5, another modified example of a semiconductor device according to an example embodiment of the inventive concepts will be described. FIG. 5 is a perspective view of another modified example of a semiconductor device according to an example embodiment.

Referring to FIG. 5, the semiconductor substrate 3 may have the first conductive lines 9 disposed on the lower insulating layer 6 thereof, as illustrated in FIGS. 1A and 1B. The first conductive lines 9 may have a lower structure LS′ disposed thereon. The lower structure LS′ may include the first electrodes 225, the data storage patterns 45, the intermediate electrodes 48, the line patterns 52, the buffer patterns 58, the second electrodes 61, and the second conductive lines 72, illustrated in FIG. 4.

The lower structure LS′ may have an upper structure US′ disposed thereon, and the upper structure US′ may be formed by rotating a structure, the same as the lower structure LS′, in the second direction Y, substantially perpendicular to the first direction X, by 90° from the first direction X. Thus, the upper structure US′ may include third electrodes 325, upper data storage patterns 345, and intermediate electrodes 348, stacked, for example sequentially stacked therein and corresponding to the first electrodes 225, the data storage patterns 45, and the intermediate electrodes 48, respectively, which are stacked, for example sequentially stacked in the lower structure LS′. The third electrodes 325 may be disposed on the second conductive lines 72. In addition, the upper structure US′ may have upper line patterns 352, upper buffer patterns 358, fourth electrodes 361, and fourth conductive lines 372, corresponding to the line patterns 52, the buffer patterns 58, the second electrodes 61, and the second conductive lines 72 of the lower structure LS′, respectively. The first conductive lines 9, the line patterns 52, and the fourth conductive lines 372 may overlap one another, and may have line shapes extending in the first direction X. The second conductive lines 72 and the upper line patterns 352 may overlap each other, and may have line shapes extending in the second direction Y, substantially perpendicular to the first direction X.

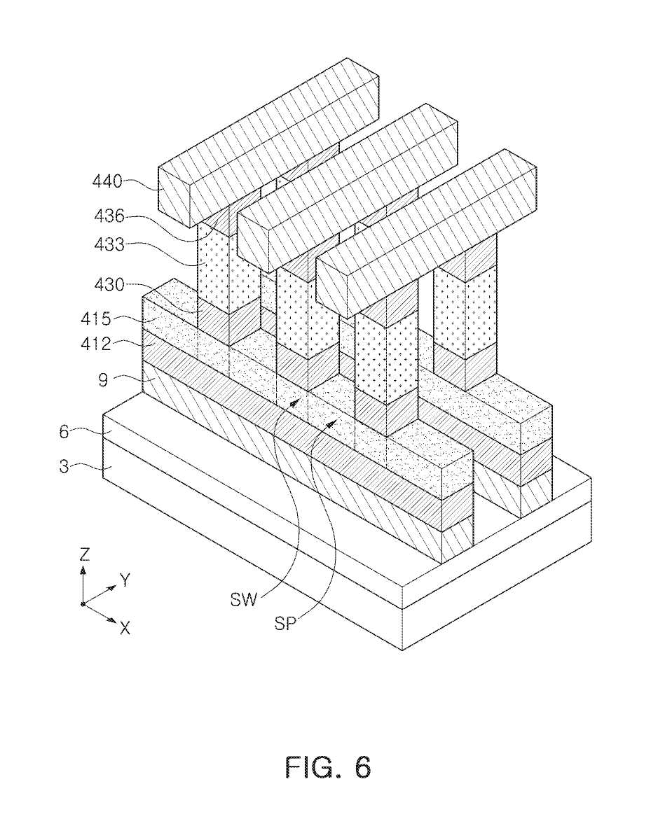

With reference to FIG. 6, another modified example of a semiconductor device according to an example embodiment of the inventive concepts will be described. FIG. 6 is a perspective view of another modified example of a semiconductor device according to an example embodiment.

Referring to FIG. 6, the semiconductor substrate 3 may have the first conductive lines 9 disposed on the lower insulating layer 6 thereof, as illustrated in FIGS. 1A and 1B. The first conductive lines 9 may have first electrodes 412 and line patterns 415 disposed thereon, to be stacked, for example sequentially stacked. The first conductive lines 9, the first electrodes 412, and the line patterns 415 may be stacked, for example sequentially stacked, and may have line shapes extending in the first direction X.

The line patterns 415 may be formed of or include the same material as the line patterns 52 illustrated in FIGS. 1A and 1B. Thus, the line patterns 415 may include threshold switching devices SW and switch separation regions SP illustrated in FIGS. 1A and 1B.

The threshold switching devices SW of the line patterns 415 may have intermediate electrodes 430, data storage patterns 433, and second electrodes 436 disposed thereon, to be stacked, for example sequentially stacked. The second electrodes 436 may have second conductive lines 440 disposed thereon. The second conductive lines 440 may extend in the second direction Y, substantially perpendicular to the first direction X.

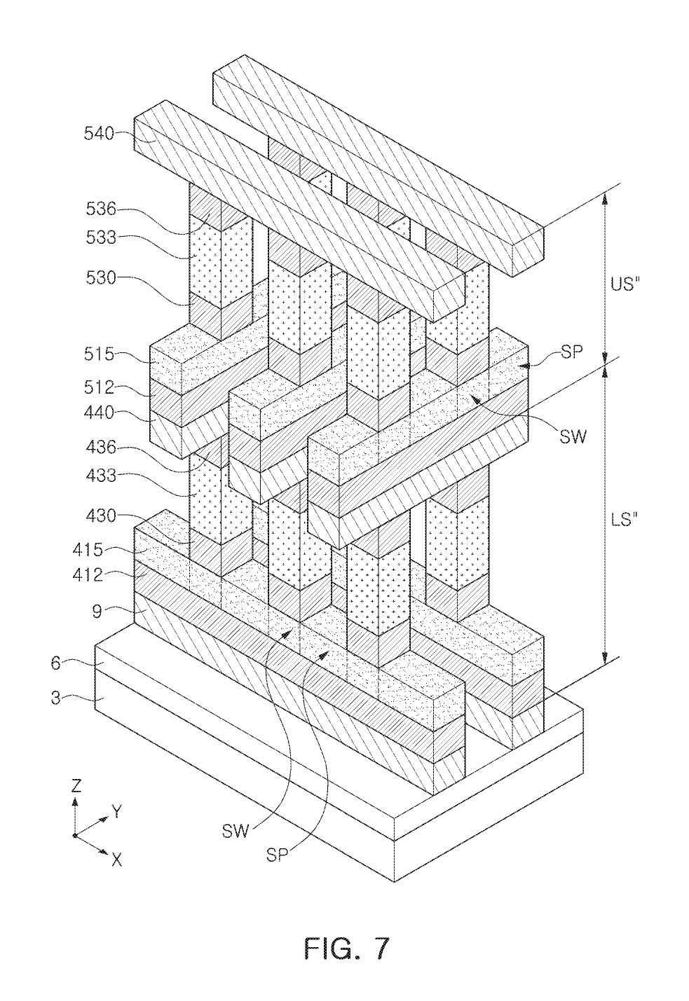

With reference to FIG. 7, another modified example of a semiconductor device according to an example embodiment of the inventive concepts will be described. FIG. 7 is a perspective view of another modified example of a semiconductor device according to an example embodiment.

Referring to FIG. 7, the semiconductor substrate 3 may have the first conductive lines 9 disposed on the lower insulating layer 6 thereof, as illustrated in FIGS. 1A and 1B. The first conductive lines 9 may have a lower structure LS″ disposed thereon. The lower structure LS″ may include the first electrodes 412, the line patterns 415, the intermediate electrodes 430, the data storage patterns 433, the second electrodes 436, and the second conductive lines 440, as illustrated in FIG. 6.

The lower structure LS″ may have an upper structure US″ disposed thereon, and the upper structure US″ may be formed by rotating a structure, the same as the lower structure LS″, in the second direction Y, substantially perpendicular to the first direction X, by 90° from the first direction X. In addition, the upper structure US″ may have third electrodes 512, upper line patterns 515, intermediate electrodes 530, data storage patterns 533, fourth electrodes 536, and fourth conductive lines 540 corresponding to the first electrodes 412, the line patterns 415, the intermediate electrodes 430, the data storage patterns 433, the second electrodes 436, and the second conductive lines 440 of the lower structure LS″, respectively. The third electrodes 512 may be disposed on the second conductive lines 440 of the lower structure LS″.

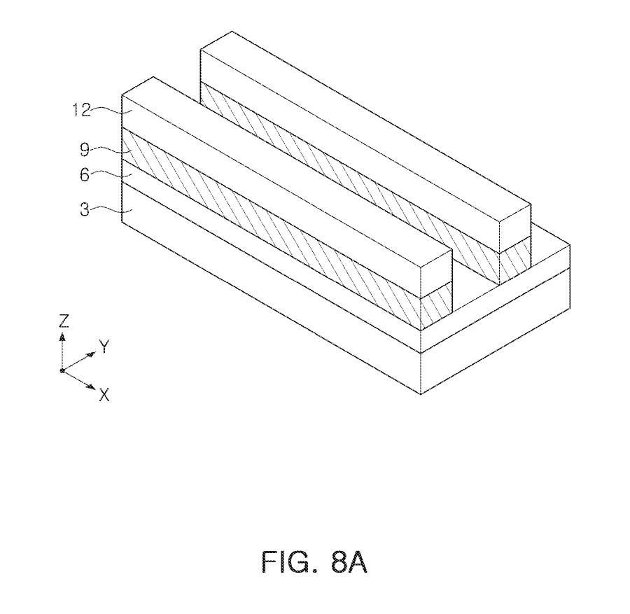

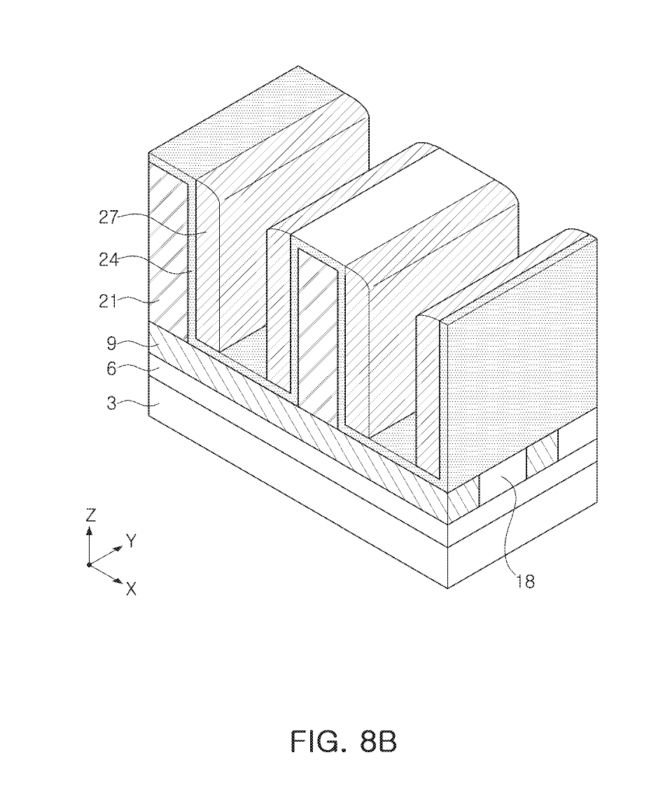

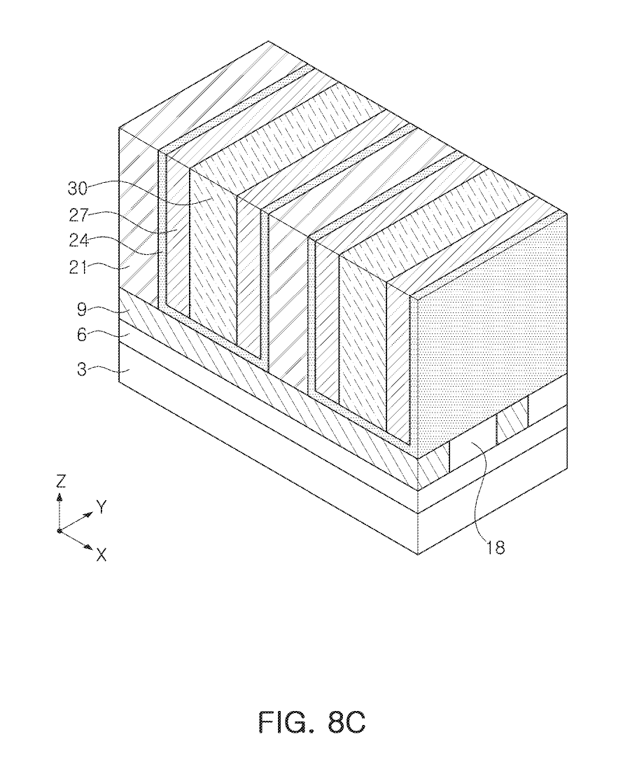

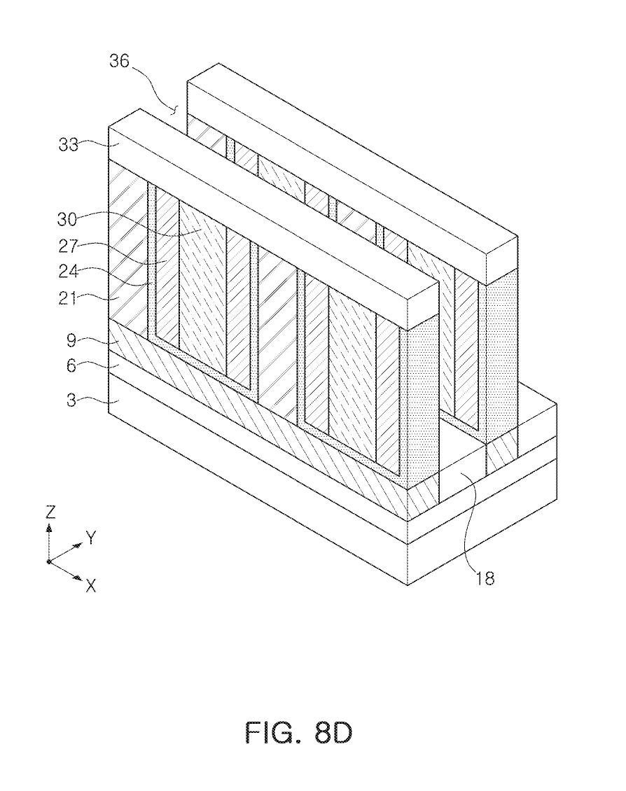

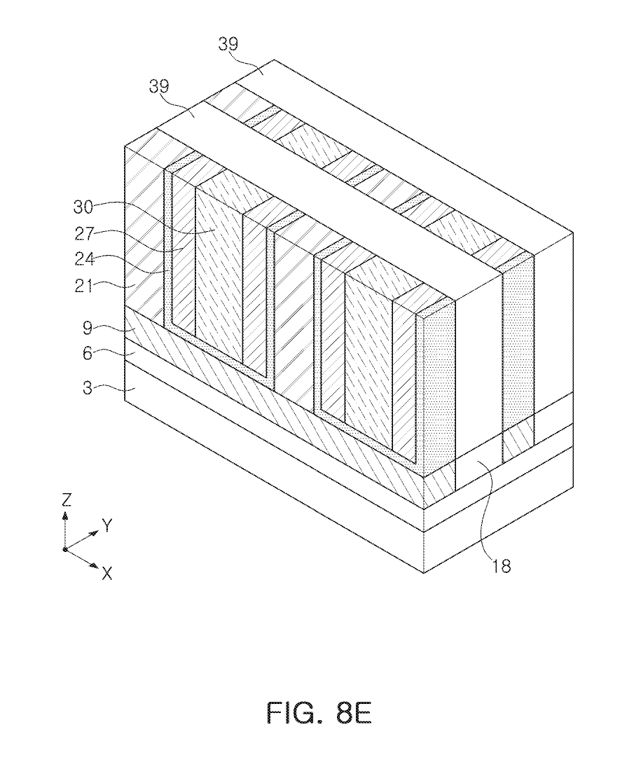

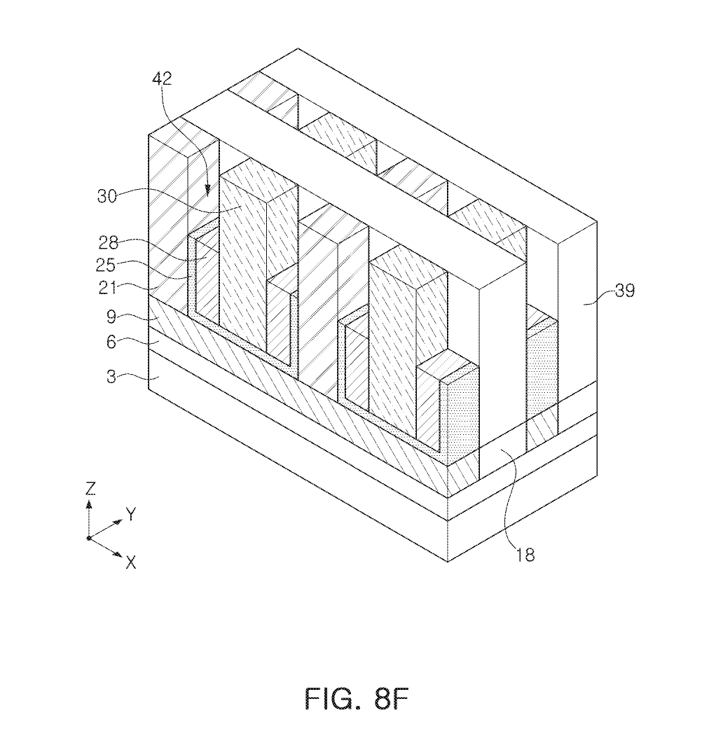

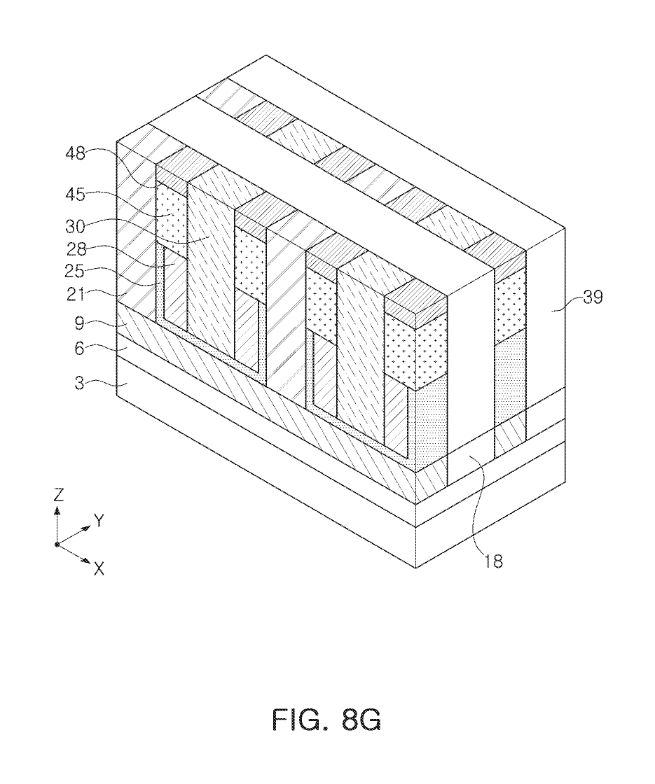

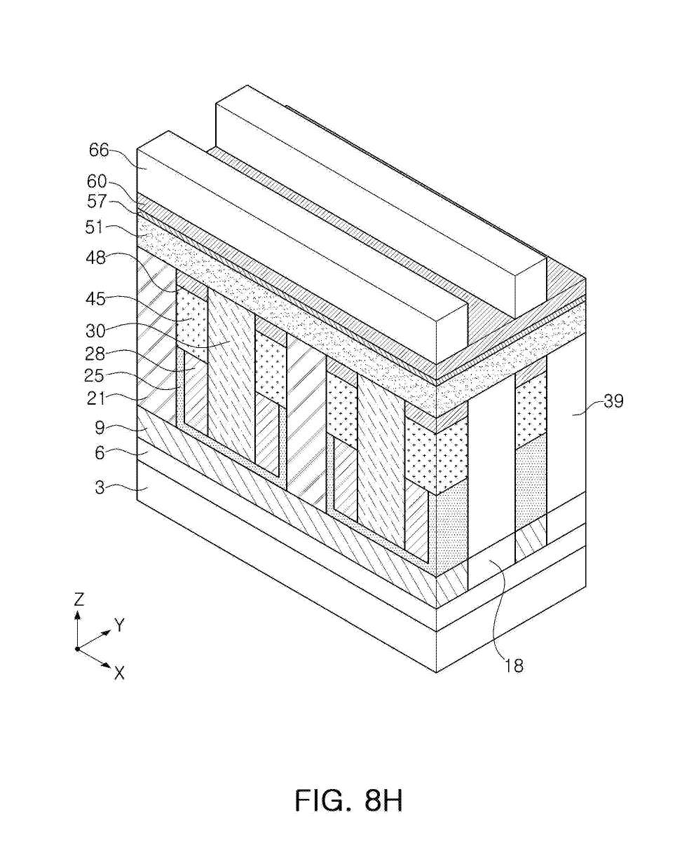

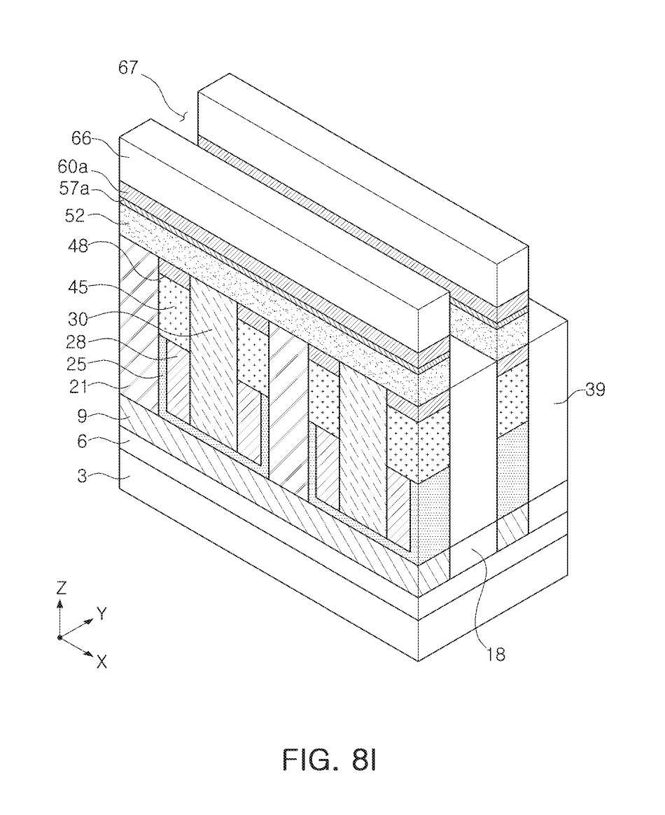

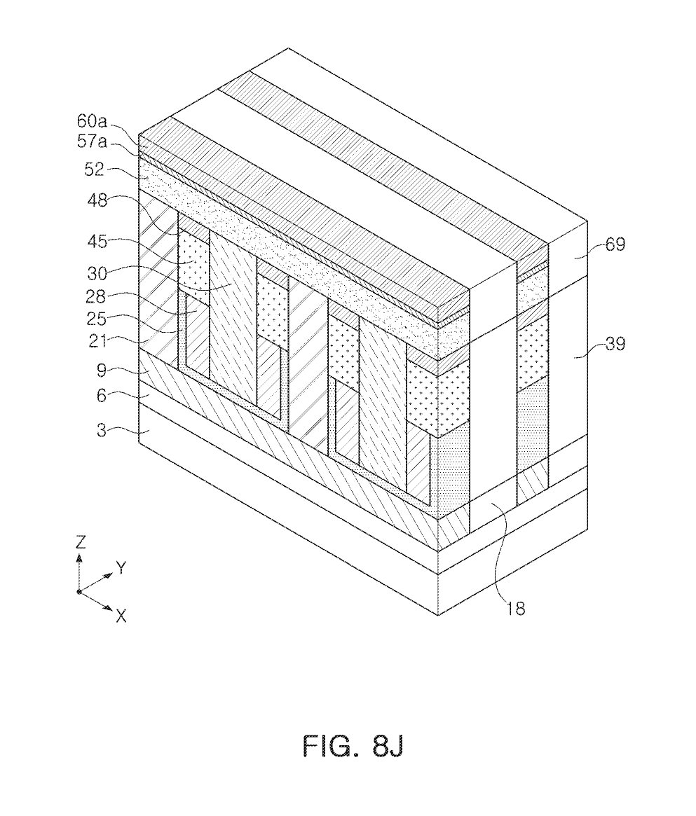

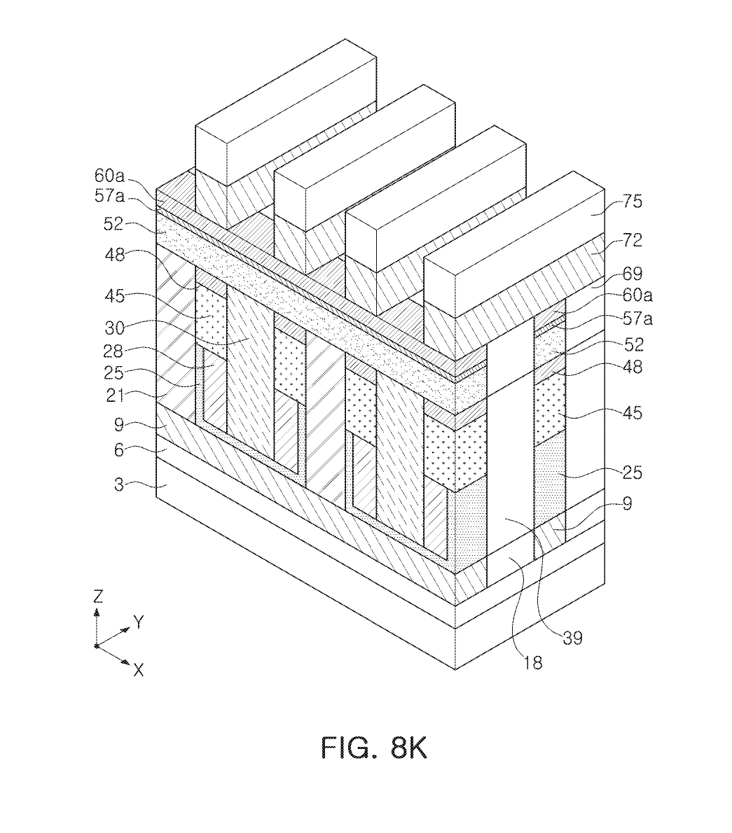

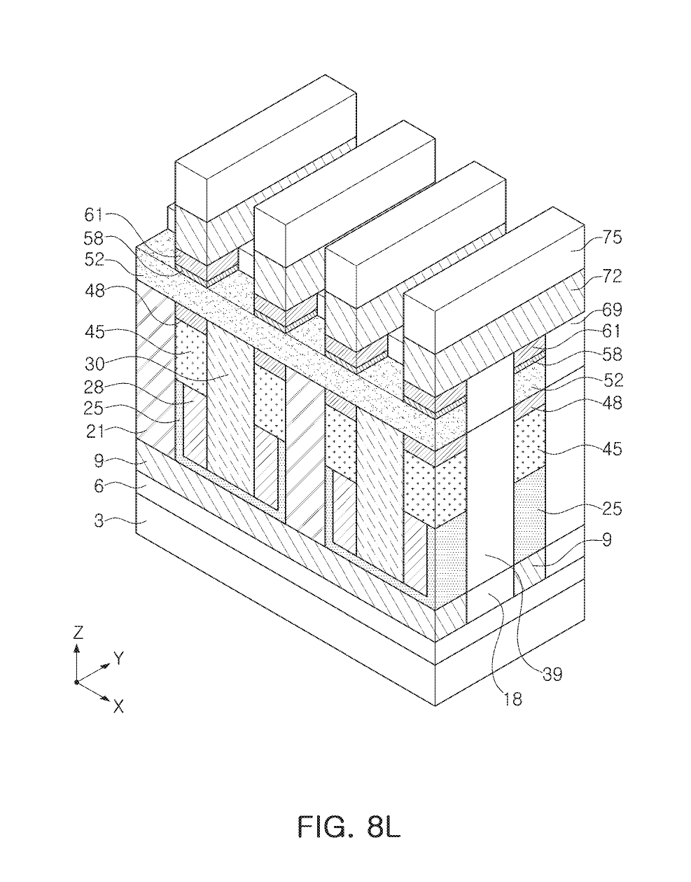

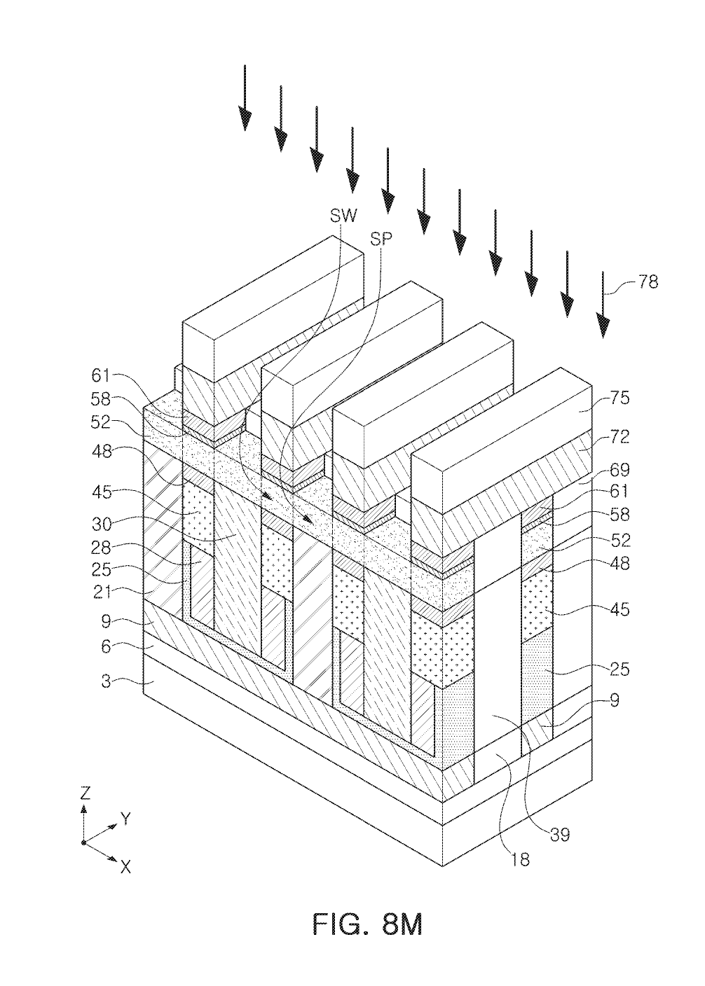

Next, an example of a method of forming a semiconductor device according to an example embodiment of the inventive concepts will be described. For example, a method of fabricating the semiconductor device described with reference to FIGS. 1A and 1B or the semiconductor device described with reference to FIGS. 3A and 3B will be described with reference to FIGS. 8A through 8M. FIGS. 8A through 8M are perspective views of an example of a method of fabricating a semiconductor device according to an example embodiment of the inventive concepts.

Referring to FIG. 8A, a lower insulating layer 6 may be formed on a semiconductor substrate 3. The semiconductor substrate 3 may be formed of or include a semiconductor material such as silicon or the like, and the lower insulating layer 6 may be formed of or include an insulating material such as silicon oxide or the like.

First conductive lines 9 may be formed on the lower insulating layer 6, to be spaced apart from each other. The formation of the first conductive lines 9 may include forming a first conductive layer on the lower insulating layer 6, forming a first mask 12 on the first conductive layer, and etching portions of the first conductive layer, using the first mask 12 as an etching mask.

Referring to FIG. 8B, first gap-fill layers 18, filling a space between the first conductive lines 9, may be formed. The formation of the first gap-fill layers 18 may include forming an insulating material layer on the semiconductor substrate 3, which has the first conductive lines 9 and the first mask 12 of FIG. 8A thereon, and planarizing the insulating material layer until the first conductive lines 9 are exposed. The first mask 12 of FIG. 8A may be removed while planarizing the insulating material layer.

First insulating patterns 21 may be formed on the first conductive lines 9 and the first gap-fill layers 18. The first conductive lines 9 may have a line shape extending in a first direction X, and the first insulating patterns 21 may have a line shape extending in a second direction Y, substantially perpendicular to the first direction X.

A first electrode layer 24 may be conformally formed on the semiconductor substrate 3 having the first insulating patterns 21. Spacers 27 may be formed on lateral surfaces of the first insulating patterns 21 covered by the first electrode layer 24. The formation of the spacers 27 may include conformally forming, on the first electrode layer 24, a spacer material layer having a greater thickness than the thickness of the first electrode layer 24, and anisotropically etching portions of the spacer material layer. The spacers 27 may be formed of or include an insulating material such as silicon nitride or silicon oxide.

Referring to FIG. 8C, second insulating patterns 30 may be formed between the first insulating patterns 21. The formation of the second insulating patterns 30 may include forming a second insulating material layer on the semiconductor substrate 3, having the spacers 27, and planarizing the second insulating material layer and the first electrode layer 24 until the first insulating patterns 21 are exposed. The second insulating patterns 30 may be formed of or include the same material as the first insulating patterns 21.

Referring to FIG. 8D, a second mask 33 may be formed on the semiconductor substrate 3 having the second insulating patterns 30. The second mask 33 may overlap the first conductive lines 9, and may have a line shape extending in the first direction X as in the first conductive lines 9.

Using the second mask 33 as an etching mask, portions of the first and second insulating patterns 21 and 30, the first electrode layer 24, and the spacers 27 may be etched to form opening portions 36 exposing the first gap-fill layers 18. The remaining portions of the first and second insulating patterns 21 and 30, the first electrode layer 24, and the spacers 27 may be etched to remain between the second mask 33 and the first conductive lines 9.

Referring to FIG. 8E, third insulating patterns 39 may be formed in the opening portions 36. The formation of the third insulating patterns 39 may include forming a third insulating material layer on the semiconductor substrate 3 having the opening portions 36 of FIG. 8D, and planarizing the third insulating material layer until the first and second insulating patterns 21 and 30 are exposed. The second mask 33 of FIG. 8D may be removed while planarizing the third insulating material layer. Therefore, the first electrode layer 24 and the spacers 27 may be exposed.

In an example embodiment, the first to third insulating patterns 21, 30, and 39 may be formed of or include the same insulating material. For example, the first to third insulating patterns 21, 30, and 39 may be formed of or include silicon oxide or silicon nitride.

In an example embodiment, the spacers 27 may be formed of or include a material having a different etching selectivity from the first to third insulating patterns 21, 30, and 39. For example, when the first to third insulating patterns 21, 30, and 39 are formed of or include silicon nitride, the spacers 27 may be formed of or include silicon oxide. Conversely, when the first to third insulating patterns 21, 30, and 39 are formed of or include silicon oxide, the spacers 27 may be formed of or include silicon nitride.

Referring to FIG. 8F, portions of the first electrode layer 24 of FIG. BE and portions of the spacers 27 of FIG. 8E may be etched to form first electrodes 25 and spacer patterns 28. The etching of the portions of the first electrode layer 24 of FIG. 8E and the portions of the spacers 27 of FIG. 8E may include etching the portions of the spacers 27 of FIG. 8E to form the spacer patterns 28, and then etching the portions of the first electrode layer 24 of FIG. 8E to form the first electrodes 25.

Regions removed by etching the portions of the first electrode layer 24 of FIG. 8E and the portions of the spacers 27 of FIG. 8E may be defined as holes 42.

Referring to FIG. 8G, data storage patterns 45 may be formed in the holes 42. In an example embodiment, the data storage patterns 45 may fill portions of the holes 42 of FIG. 8F. The data storage patterns 45 may be formed of or include the phase change memory material, as described in relation to FIGS. 1A and 1B. Intermediate electrodes 48 may be formed on the data storage patterns 45 to fill the remaining portions of the holes 42 of FIG. 8F.

Referring to FIG. 8H, a threshold switch layer 51 may be formed to cover the first to third insulating patterns 21, 30, and 39 and the intermediate electrodes 48. The threshold switch layer 51 may be formed of or include the threshold switch material as described in relation to FIGS. 1A and 1B, for example, a chalcogenide-based threshold switch material.

A buffer layer 57 may be disposed on the threshold switch layer 51. The buffer layer 57 may also be formed of or include a conductive material layer or of a thin carbon material layer that may be electrified. A second electrode layer 60 may be formed on the buffer layer 57. The buffer layer 57 may have be thinner than the second electrode layer 60. A third mask 66 may be formed on the second electrode layer 60. The third mask 66 may have a line shape overlapping the first conductive lines 9.

In an example embodiment, the formation of the buffer layer 57 may be omitted.

Referring to FIG. 8I, portions of the second electrode layer 60, the buffer layer 57, and the threshold switch layer 51 may be etched, for example sequentially etched, using the third mask 66 as an etching mask, to form second electrode lines 60a, buffer lines 57a, and line patterns 52. The exposed portions of the second electrode layer 60, the buffer layer 57, and the threshold switch layer 51 may be defined as opening portions 67. The opening portions 67 may expose the third insulating patterns 39. The line patterns 52 may overlap the first conductive lines 9.

Referring to FIG. 8J, second gap-fill layers 69, filling a space between the opening portions 67 of FIG. 8I, may be formed. The second gap-fill layers 69 may be formed of or include an insulating material such as silicon oxide or the like. The formation of the second gap-fill layers 69 may include forming a gap-fill material layer, filling the opening portions 67 of FIG. 8I and covering the third mask 66 of FIG. 8I, and planarizing the gap-fill material layer until the second electrode lines 60a are exposed. The third mask 66 of FIG. 8I may be removed while planarizing the gap-fill material layer.

Referring to FIG. 8K, second conductive lines 72 and a fourth mask 75 may be formed on the second gap-fill layers 69 and the second electrode lines 60a, to be stacked, for example sequentially stacked. The formation of the second conductive lines 72 may include forming a conductive material layer on the second gap-fill layers 69 and the second electrode lines 60a, forming a fourth mask 75 on the conductive material layer, and etching portions of the conductive material layer, using the fourth mask 75 as an etching mask.

The second conductive lines 72 may intersect the first conductive lines 9 and the line patterns 52. For example, the first conductive lines 9 and the line patterns 52 may have line shapes extending in the first direction X, and the second conductive lines 72 may have a line shape extending in the second direction Y, substantially perpendicular to the first direction X.

Referring to FIG. 8L, portions of the second electrode lines 60a of FIG. 8K may be etched, using the second conductive lines 72 and the fourth mask 75 as etching masks, to form second electrodes 61. The buffer lines 57a may be exposed while forming the second electrodes 61. The buffer lines 57a may hinder or prevent the line patterns 52 from being damaged, while etching the portions of the second electrode lines 60a of FIG. 8K.

Portions of the exposed buffer lines 57a may be etched to form buffer patterns 58. Thus, the buffer patterns 58 and the second electrodes 61 may be stacked, for example sequentially stacked, and may be interposed between the second conductive lines 72 and the line patterns 52.

Referring to FIG. 8M, a process 78 of injecting or doping an element, which may change physical properties of the threshold switch material forming the line patterns 52, into the line patterns 52, may be performed. As described above, the element, which may change the physical properties of the threshold switch material, may be defined as an “impurity element”, as illustrated in FIGS. 1A and 1B.

The impurity element may be any one of N, As, Si, Ge, or O. The process 78 of injecting the impurity element into the line patterns 52 may be an ion implanting process or a plasma doping process.

In an example embodiment, the process 78 may be an ion implanting process, using the second conductive lines 72 and the fourth mask 75 as ion implanting masks. Thus, the impurity element may be injected into regions SP of the line patterns 52 that do not overlap the second conductive lines 72.

In an example embodiment, the process 78 may be a plasma doping process of doping nitrogen into the regions SP of the line patterns 52 that do not overlap the second conductive lines 72.

Thus, the regions SP of the line patterns 52 that do not overlap the second conductive lines 72 may be injected or doped with the impurity element, and may be defined as switch separation regions SP. In addition, regions SW of the line patterns 52 that overlap the second conductive lines 72 may be defined as threshold switching devices SW.

Thus, the line patterns 52 may include the threshold switching devices SW and the switch separation regions SP. The material types of the line patterns 52 have been described in relation to FIGS. 1A and 1B, thus a detailed description thereof will be omitted herein.

Returning to FIG. 1A, a gap-fill material layer may be formed on the semiconductor substrate 3 having the line patterns 52, the line patterns 52 having the threshold switching devices SW and the switch separation regions SP, and third gap-fill layers 81 may be formed by planarizing the gap-fill material layer until the second conductive lines 72 are exposed. The fourth mask 75 of FIG. 8M may be removed while planarizing the gap-fill material layer. Thus, the semiconductor device described with reference to FIG. 1A or 2 may be fabricated.

A modified example of a method of fabricating a semiconductor device according to an example embodiment may include rotating the structure of the semiconductor device described with reference to FIG. 1A or 2 by 90° on the X-Y plane, and then fabricating the semiconductor device described in FIGS. 3A and 3B by repeating the foregoing processes, from the process of forming the first insulating patterns 21 described in relation to FIG. 8B, to the process 78, described in relation to FIG. 8M.

In another modified example of a method of fabricating a semiconductor device according to an example embodiment, the formation of the first electrodes 225, the data storage patterns 45, and the intermediate electrodes 48, stacked, for example sequentially stacked, and described in relation to FIG. 4, may include forming, for example sequentially forming a first electrode material layer, a data storage material layer and an intermediate electrode material layer, and then patterning the first electrode material layer, the data storage material layer, and the intermediate electrode material layer by a patterning process, using a photolithography process.

Another modified example of a method of fabricating a semiconductor device according to an example embodiment may include forming the line patterns 415 of FIG. 6, and then forming the data storage patterns 433 of FIG. 6.

As set forth above, according to the various example embodiments, a semiconductor device having threshold switching devices and able to improve a degree of integration may be provided.

According to the various example embodiments, the threshold switching devices SW may be disposed in the line patterns 52, which may reduce degradation due to etching damage. Thus, the various example embodiments may provide the threshold switching devices SW, which may reduce degradation due to etching damage.

According to the various example embodiments, a single line pattern 52 may include the threshold switching devices SW and the switch separation regions SP between the threshold switching devices SW. The switch separation regions SP may electrically separate memory cells, while being disposed in the same line pattern as the threshold switching devices SW. The memory cells may include the threshold switching devices SW.

According to the various example embodiments, as described in relation to FIG. 8M, the impurity element may be injected or doped into the regions of the line patterns 52 that do not overlap the second conductive lines 72, to form the switch separation regions SP. The regions in which the switch separation regions SP have not been formed in the line patterns 52 may be defined as the threshold switching devices SW. Thus, since the threshold switching devices SW may be formed in portions of the line patterns 52 that intersect the second conductive lines 72, a degree of alignment between the threshold switching devices SW and the second conductive lines 72 may be increased. As described above, the threshold switching devices SW may be aligned with the second conductive lines 72 to thus improve distribution characteristics or performance of the semiconductor device.

While example embodiments have been shown and described above, it will be apparent to those skilled in the art that modifications and variations could be made without departing from the scope of the inventive concepts, as defined by the appended claims.

1. A semiconductor device comprising:
a line pattern on a semiconductor substrate and including threshold switching devices and switch separation regions;
data storage patterns overlapping the threshold switching devices; and
intermediate electrodes between the data storage patterns and the threshold switching devices,
the line pattern including an impurity element, and
a concentration of the impurity element in the switch separation regions being higher than the concentration of the impurity element in the threshold switching devices.

2. The semiconductor device of claim 1, wherein:
the threshold switching devices include an ovonic threshold switch material, and
the switch separation regions include the ovonic threshold switch material doped with the impurity element.

3. The semiconductor device of claim 1, wherein the data storage patterns include a phase change memory material.

4. The semiconductor device of claim 1, wherein the impurity element comprises at least one of nitrogen (N), arsenic (As), silicon (Si), germanium (Ge) or oxygen (O).

5. The semiconductor device of claim 1, further comprising:
a first conductive line on the semiconductor substrate and extending in a first direction; and
second conductive lines on the semiconductor substrate and extending in a second direction, the second direction being substantially perpendicular to the first direction, wherein,
the line pattern is on the first conductive line and extends in the first direction,
the threshold switching devices included in the line pattern are below the second conductive lines and overlap the second conductive lines, and
the data storage patterns are between the threshold switching devices and the first conductive line.

6. The semiconductor device of claim 5, further comprising:
a first electrode between the first conductive line and the data storage patterns;
intermediate electrodes between the data storage patterns and the threshold switching devices; and
second electrodes between the threshold switching devices and the second conductive lines, wherein,
the first electrode includes a first portion and a second portion opposite the first portion on the first conductive line, and a connection portion contacting the first conductive line and connecting lower regions of the first portion and the second portion, and
the data storage patterns include a first data storage pattern contacting the first portion of the first electrode and a second data storage pattern contacting the second portion of the first electrode.

7. The semiconductor device of claim 6, further comprising:
a first spacer pattern, a second spacer pattern, and an insulating pattern on the connection portion of the first electrode, wherein,
the first spacer pattern contacts the first portion of the first electrode,
the second spacer pattern contacts the second portion of the first electrode, and
the insulating pattern is between the first spacer pattern and the second spacer pattern.

8. The semiconductor device of claim 7, wherein:
a lower surface of the first data storage pattern contacts an upper surface of the first portion of the first electrode and an upper surface of the first spacer pattern, and
a lower surface of the second data storage pattern contacts an upper surface of the second portion of the first electrode and an upper surface of the second spacer pattern.

9. The semiconductor device of claim 6, further comprising:
buffer patterns between the second electrodes and the threshold switching devices, wherein the buffer patterns include a different material from the second electrodes.

10. The semiconductor device of claim 1, further comprising:
a first conductive line on the semiconductor substrate and extending in a first direction; and
first electrodes between the first conductive line and the data storage patterns;
intermediate electrodes between the data storage patterns and the threshold switching devices;
second conductive lines on the semiconductor substrate, extending in a second direction, the second direction being substantially perpendicular to the first direction, and on a level higher than a level of the line pattern; and
second electrodes between the threshold switching devices and the second conductive lines,
wherein the first electrodes, the data storage patterns and the intermediate electrodes are stacked on the first conductive lines and have lateral surfaces aligned in a vertical direction thereof.

11. The semiconductor device of claim 1, further comprising
a first conductive line on the semiconductor substrate and extending in a first direction; and
second conductive lines on the semiconductor substrate, extending in a second direction, the second direction being substantially perpendicular to the first direction, and on a level higher than a level of the line pattern,
wherein the threshold switching devices of the line pattern are between the first conductive line and the second conductive lines, and
the data storage patterns are between the threshold switching devices of the line pattern and the second conductive lines.

12. A semiconductor device comprising:
first conductive lines on a semiconductor substrate and extending in a first direction; and
a lower structure on the first conductive lines,
wherein the lower structure includes,
line patterns on the first conductive lines and extending in the first direction;
second conductive lines on a level higher than a level of the line patterns and extending in a second direction, the second direction being substantially perpendicular to the first direction; and
data storage patterns between the first conductive lines and the second conductive lines,
wherein at least one of the line patterns includes threshold switching devices overlapping the second conductive lines, and switch separation regions between the threshold switching devices and having a different impurity concentration than the threshold switching devices.

13. The semiconductor device of claim 12, wherein:
a threshold voltage of the switch separation regions is higher than a threshold voltage of the threshold switching devices, or an off-current of the switch separation regions is lower than an off-current of the threshold switching devices.

14. The semiconductor device of claim 12, wherein the line patterns include a threshold switch material and a switch separation material, the switch separation material including the threshold switch material doped with an element changing physical properties of the threshold switch material.

15. The semiconductor device of claim 12, further comprising:
an upper structure on the lower structure, the upper structure including a rotated structure that is a same structure as the lower structure, in the second direction by 90°, from the first direction, wherein,
the first direction and the second direction are on a same plane, and
the upper structure is electrically connected to the second conductive lines of the lower structure.

16. A semiconductor device comprising:
a line pattern on a semiconductor substrate and including a plurality of threshold switching devices alternating with a plurality of switch separation regions in a length direction of the line pattern, the line pattern including an impurity element; and
data storage patterns overlapping the threshold switching devices; at least one of,
a threshold voltage of the switch separation regions being higher than a threshold voltage of the threshold switching devices; and
an off-current of the switch separation regions being lower than an off-current of the threshold switching devices;
a concentration of the impurity element in the plurality of switch separation regions being higher than the concentration of the impurity element in the plurality of threshold switching devices.

17. The semiconductor device of claim 16, wherein:
the line pattern includes an impurity element; and
a concentration of the impurity element in the switch separation regions is higher than the concentration of the impurity element in the threshold switching devices.

18. (canceled)

19. The semiconductor device of claim 16, further comprising:
intermediate electrodes between the data storage patterns and the threshold switching devices.

20. The semiconductor device of claim 16, further comprising:
a first conductive line on the semiconductor substrate and extending in a first direction; and
second conductive lines on the semiconductor substrate and extending in a second direction, the second direction being substantially perpendicular to the first direction, wherein,
the line pattern is on the first conductive line and extends in the first direction,
the threshold switching devices are below the second conductive lines, and
the data storage patterns are between the threshold switching devices and the first conductive line.

21. The semiconductor device of claim 12, wherein a concentration of an impurity element in the switch separation regions is higher than the concentration of the impurity element in the threshold switching devices.
